(19) United States
(12) Patent Application Publication
(10) Pub. No.: US 2002/0022340 A1
(43) Pub. Date: Feb. 21, 2002

(54) METHOD OF FORMING A SHALLOW TRENCH ISOLATION

(76) Inventors: TONY LIN, KAOHSIUNG HSIEN (JP); KUO-TAI HUANG, HSINCHU (TW)

Correspondence Address: J C Patents Inc, 4 Venture, Suite 250, Irvine, CA, 92618, US

(21) Appl. No.: 09/200,282

(22) Filed: Nov. 24, 1998

(51) Int. Cl. H01L 21/76

(52) U.S. Cl. 438/435

(57) ABSTRACT

A method for forming a shallow trench isolation structure provides a substrate and a pad oxide layer is formed on the substrate to protect the substrate. A silicon nitride layer as a hard mask layer is deposited on the pad oxide layer, a shallow trench is defined by photolithography and etching. A liner oxide layer is formed on the surface of the shallow trench by thermal oxidation and a stress buffer layer is deposited conformal to the substrate by chemical vapor deposition. The stress buffer layer is used to release the stress and eliminate dislocations in the invention.

### BACKGROUND OF THE INVENTION

1. Field of the Invention

The present invention relates to a method for manufacturing a semiconductor device. More particularly, the present invention relates to a method for forming a device isolation of a semiconductor device.

2. Description of the Related Art

An isolation regions is formed in an integrated circuit for preventing short current occurred between adjacent device regions on a substrate. Conventionally, local oxidation of silicon (LOCOS) technique is widely utilized in semiconductor industry to provide isolation regions on semiconductor device. However, since the internal stress generation and bird's beak encroachment in the isolation structures, LOCOS cannot effectively isolate devices.

Shallow trench isolation (STI) technique is developed to improve the bird's beak encroachment of the LOCOS to achieve the effective isolation. Typically, the STI process comprises the steps of using a mask defined and patterned a shallow trench on a substrate by anisotropic etching process; filling the shallow trench with oxide for use as a device isolation structure; the surface of the isolation structure and the surface of the substrate are equal in height. FIG. 1, which is a schematic, cross-sectional view, illustrates a conventional shallow trench isolation structure 20, the devices are formed on the substrate 11. The field effect transistors (FETs) 14 and 16 are formed around the shallow trench isolation structure, wherein the FETs include an N-type source/drain region in the substrate, a gate oxide and a gate electrode.

FIGS. 2A through 2E are schematic, cross-sectional views showing the progression of the conventional manufacturing steps for a shallow trench isolation structure. Referring to FIG. 2A, an oxide layer 12 is formed as a pad oxide layer on the substrate 10. The pad oxide layer 12 is used to protect the surface of the substrate 10; the pad oxide layer 12 is removed before a gate oxide layer is formed in a subsequent step. A silicon nitride layer 15 is formed on the pad oxide layer 12, for example, by chemical vapor deposition (CVD). The silicon nitride layer 15 is patterned by photolithography and etching, and the silicon nitride layer 15 serves as a hard mask layer.

Referring to FIG. 2B, a shallow trench 30 is formed in the substrate 10 by penetrating through the pad oxide layer 12 and the substrate 10. A pad oxide layer 12a is formed while performing the process of forming the shallow trench 30.

As shown in FIG. 2C, a liner oxide layer 22 is formed on the surface of the shallow trench 30 within the substrate 10 by thermal oxidation. An oxide layer 32 is deposited over the silicon nitride layer 15 and within the shallow trench 30 by atmospheric pressure chemical vapor deposition (APCVD) with tetra-ethyl-ortho-silicate (TEOS) as a gas source. A densification step is performed on the oxide layer 32 under 1000° C., and the duration of the step is about 10-30 min.

As shown in FIG. 2D, the silicon nitride layer 15 is used as a polishing stop, and the oxide layer 32 above the surface of the silicon nitride layer 15 is removed by chemical-mechanical polishing (CMP) after the densification step. Thus, an oxide plug 32a is formed within the shallow trench 30.

As shown in FIG. 2E, the silicon nitride layer 15 is removed by using hot phosphoric acid (H₃PO₄), and the pad oxide layer 12a is removed by using hydrogen fluoride (HF). However, an oxide plug 32b is formed because a portion of the oxide plug 32a is removed while the step of removing the pad oxide layer 12a is performed. Because the thermal expansion coefficients of silicon of the substrate 10 and silicon dioxide of the liner oxide layer 22 are different, therefore warpage and defects occur in the substrate surface from stress while performing a densification step. Line defects in crystal material are commonly known as dislocations; the dislocations are caused by crystal lattices suffering excessive compression and tension, and the presence of dislocations in the substrate can affect the mechanical properties and electric properties of the substrate. For example, dopants in the source/drain region can diffuse along the defects when the dislocations expand to the source/drain region. Thus, this phenomenon causes leakage current and reduces conductive quality, and the situation worsens when integration of elements in integrated circuits increases and line widths and geometries for semiconductor devices decrease.

### SUMMARY OF THE INVENTION

Accordingly, the present invention provides a method for forming a shallow trench isolation structure on a substrate. A stress buffer layer is provided in the shallow trench isolation structure to release stress and eliminate dislocations of the substrate during densification or other processes.

To achieve these and other advantages and in accordance with the purpose of the invention, as embodied and broadly described herein, the invention provides a method for forming a shallow trench isolation structure. A substrate is provided, and a pad oxide layer is formed on the substrate to protect the substrate. A silicon nitride layer is deposited as a hard mask layer on the pad oxide layer. A shallow trench is formed by photolithography and etching. A liner oxide layer is formed on the surface of the shallow trench by thermal oxidation. A stress buffer layer, such as a silicon-oxy-nitride (SiOₓN_{y}) layer or a silicon nitride (SiN_{y}) layer, is deposited on the liner oxide. In one embodiment of the present invention, the stress buffer layer is formed to comform to the substrate. The thickness of the stress buffer layer is preferably about 50-500 Å. The stress buffer layer is provided in the shallow trench isolation structure to release stress and eliminate dislocations of the substrate during densification or other processes.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic, cross-sectional view showing the conventional structure of a shallow trench isolation;

FIGS. 2A through 2E are schematic, cross-sectional views showing the progression of manufacturing steps for a shallow trench isolation; and

FIGS. 3A through 3F are schematic, cross-sectional views showing the progression of manufacturing steps for a shallow trench isolation according to one preferred embodiment of this invention.

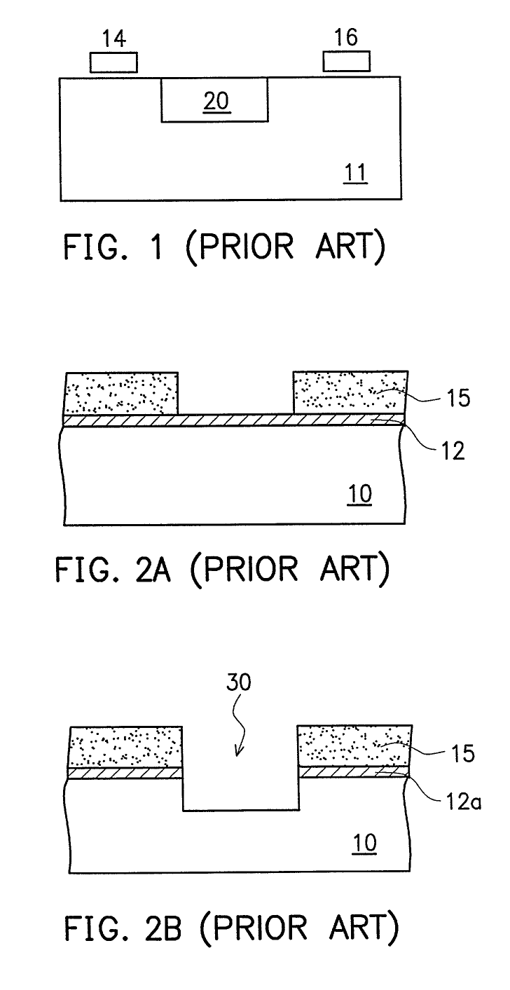

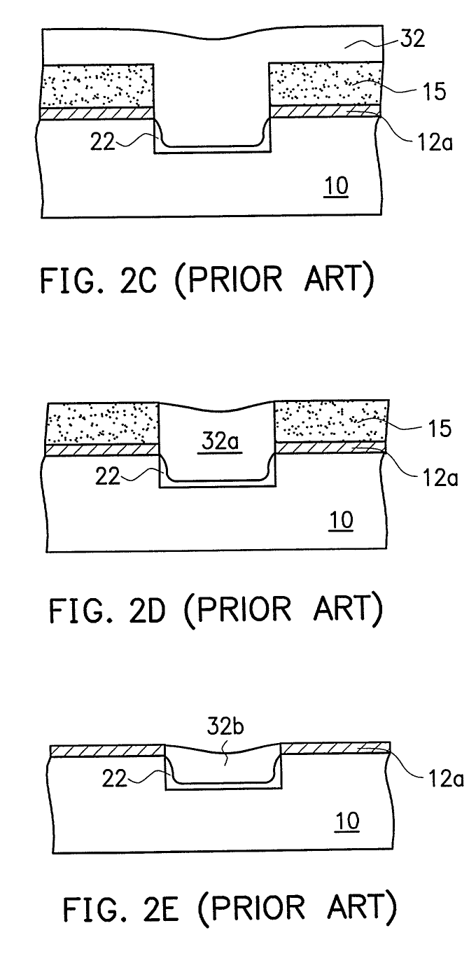

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

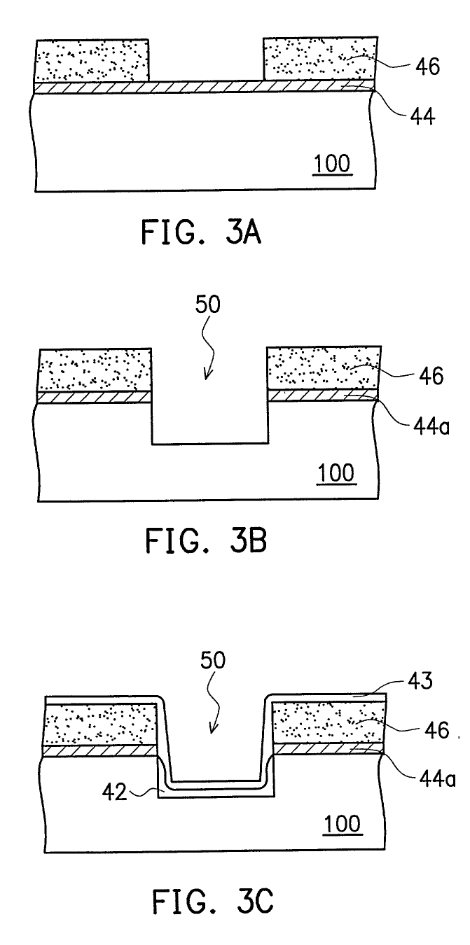

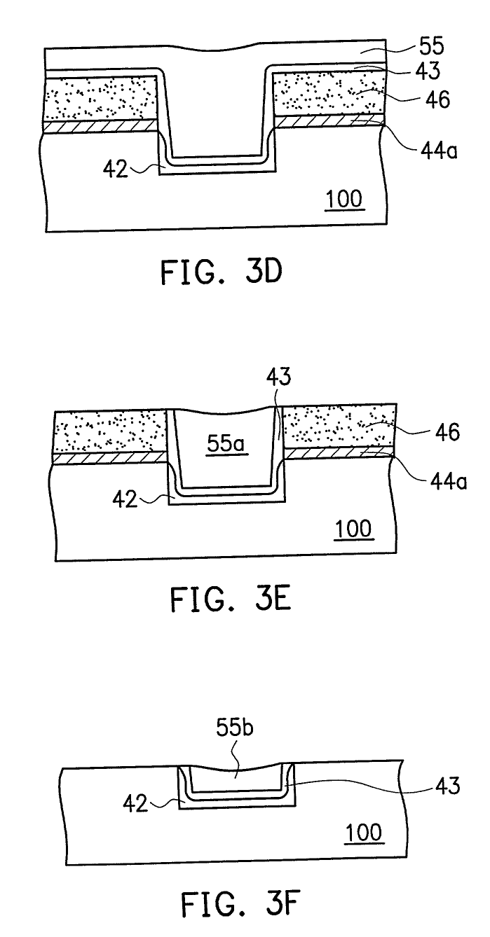

FIGS. 3A through 3F are schematic, cross-sectional views showing the progression of manufacturing steps for a shallow trench isolation according to one preferred embodiment of this invention. Referring to FIG. 3A, a substrate 100 is provided, and an oxide layer 44 is formed as a pad oxide layer on the substrate 100 to protect the surface of the substrate 100. A hard mask layer such as a silicon nitride layer is formed on the pad oxide layer 44, for example, by chemical vapor deposition (CVD). The silicon nitride layer 46 is defined by photolithography and etching, and the silicon nitride layer 46 serves as a hard mask layer.

Referring to FIG. 3B, a shallow trench 50 in the substrate 100 is formed by penetrating through the pad oxide layer 44 and the substrate 100. A pad oxide layer 44a is formed while performing the process of forming the shallow trench 50.

As shown in FIG. 3C, a liner oxide layer 42 is formed on the shallow trench 50 surface within the substrate 100, for example, by thermal oxidation. A stress buffer layer 43, such as a silicon-oxy-nitride (SiOₓN_{y}) or a silicon nitride (SiN_{y}), is deposited conformal to the substrate 100, for example, by chemical vapor deposition (CVD). The thickness of the stress buffer layer 43 is about 50-500 Å, the stress buffer layer 43 is used to release the stress and eliminate dislocations.

As shown in FIG. 3D, an oxide layer 55 is deposited over the stress buffer layer 43 and within the shallow trench 50, for example, by atmospheric pressure chemical vapor deposition (APCVD) with tetra-ethyl-ortho-silicate (TEOS) as a gas source. A densification step is performed on the oxide layer 55 sequentially.

As shown in FIG. 3E, the silicon nitride layer 46 is used as a polishing stop, and a portion of the oxide layer 55 and the stress buffer layer 43 above the surface of the silicon nitride layer 46 are removed, for example, by chemical-mechanical polishing (CMP) after the densification step. Thus, an oxide plug 55a is formed within the shallow trench 50.

As shown in FIG. 3F, the silicon nitride layer 46 is removed, for example, by using a hot phosphoric acid (H₃PO₄), and the pad oxide layer 44a is removed, for example, by using hydrogen fluoride (HF). However, an oxide plug 55b is formed because a portion of the oxide plug 55a is removed while the step of removing the pad oxide layer 44a is performed.

(1) The method of the present invention for manufacturing a shallow trench isolation structure provides a stress buffer layer, preferably a silicon-oxy-nitride or a silicon nitride layer, in the shallow trench isolation to release stress during densification or other processes. Therefore, the present invention can eliminate dislocations in the substrate.

(2) The method of the present invention for manufacturing a shallow trench isolation structure provides a stress buffer layer, and can avoid dopants in the source/drain region diffusing along the defects when the dislocations expand to the source/drain region, and prevent leakage current.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming a shallow trench isolation structure on a substrate, comprising the steps of:
Providing a hard mask layer on said substrate;
patterning the hard mask layer to form a shallow trench in the substrate;
forming a liner oxide layer on the shallow trench surface;
forming a stress buffer layer on the liner oxide layer;
forming an oxide layer over the patterned hard mask layer and filling the shallow trench therewith; and
removing a portion of the oxide layer and the patterned hard mask layer until exposing the substrate.

2. The method of claim 2, wherein the hard mask layer includes a silicon nitride layer.

3. The method of claim 1, wherein the liner oxide layer includes a silicon dioxide layer.

4. The method of claim 3, wherein the step of forming the liner oxide layer includes using thermal oxidation.

5. The method of claim 1, wherein the stress buffer layer includes a silicon-oxy-nitride layer.

6. The method of claim 1, wherein the stress buffer layer includes a silicon nitride layer.

7. The method of claim 5, wherein the step of forming the stress buffer layer includes using chemical vapor deposition.

8. The method of claim 1, wherein the oxide layer includes a silicon dioxide layer.

9. The method of claim 8, wherein the step of forming the oxide layer includes using chemical vapor deposition.

10. The method of claim 1, wherein the step of removing a portion of the oxide layer includes using chemical-mechanical polishing.

11. The method of claim 1, wherein the step of removing the patterned hard mask layer includes using wet etching.

12. A method for forming a shallow trench isolation structure, comprising the steps of:
providing a substrate;
forming a shallow trench in the substrate;
forming a liner oxide layer on the shallow trench surface; and
forming a stress buffer layer on the liner oxide layer.

13. The method of claim 12, wherein the linear oxide layer includes a silicon dioxide layer.

14. The method of claim 13, wherein the step of forming the liner oxide layer includes using thermal oxidation.

15. The method of claim 12, wherein the stress buffer layer includes a silicon-oxy-nitride layer.

16. The method of claim 12, wherein the stress buffer layer includes a silicon nitride layer.

17. The method of claim 15, wherein the step of forming the stress buffer layer includes using chemical vapor deposition.

18. A method for reducing stress of a shallow trench isolation structure, comprising the steps of:
providing a substrate;
forming a pad oxide layer on the substrate;
forming a silicon nitride layer on the pad oxide layer;
patterning the silicon nitride layer, the pad oxide layer and the substrate;
forming a shallow trench in the substrate;
forming a liner oxide layer on the shallow trench surface within the substrate;
forming a stress buffer layer conformal to the substrate;
forming an oxide layer overlying the stress buffer layer and filling the shallow trench therewith; and
removing a portion of the oxide layer, the stress buffer layer, the pad oxide layer and the silicon nitride layer until exposing the substrate.

19. The method of claim 18, wherein the stress buffer layer includes a silicon-oxy-nitride layer.

20. The method of claim 18, wherein the stress buffer layer includes a silicon nitride layer.
